(19) United States
(12) Patent Application Publication
(10) Pub. No.: US 2026/0367166 A1
(43) Pub. Date: Nov. 19, 2026

(54) INSULATION RESISTANCE MEASUREMENT SYSTEM AND METHOD FOR FUEL CELL VEHICLES

(71) Applicants: Hyundai Motor Company, Seoul (KR); Kia Corporation, Seoul (KR)

(72) Inventors: Mi Sun Kim, Hwaseong-si (KR); Keun Bong Ham, Hwaseong-si (KR)

(73) Assignees: Hyundai Motor Company, Seoul (KR); Kia Corporation, Seoul (KR)

(21) Appl. No.: 19/400,792

(22) Filed: Nov. 25, 2025

(30) Foreign Application Priority Data
May 19, 2025 (KR) 10-2025-0064288

(51) Int. Cl. G01R 31/389

(52) U.S. Cl. CPC G01R 31/389

(57) ABSTRACT

An insulation resistance measurement system for fuel cell vehicles is provided. The system includes an insulation resistance measurement circuit connected to the output terminal of a fuel cell that supplies electrical power. This circuit is configured to measure the insulation resistance value of the vehicle. A voltage measurement circuit is included to monitor the voltage at the fuel cell's output terminal during the on and off states of a relay incorporated within the insulation resistance measurement circuit. A controller is configured to operate the relay based on the measured voltage, determine whether the voltage in the relay's on-state has stabilized, and calculate the insulation resistance using the voltage measured in the stabilized state.

### CROSS-REFERENCE TO RELATED APPLICATIONS

This application claims, under 35 U.S.C. § 119A, the benefit of priority to Korean Patent Application No. 10-2025-0064288 filed on May 19, 2025, the entire contents of which are incorporated herein by reference in its entirety.

### BACKGROUND

### Technical Field

The present disclosure relates to an insulation resistance measurement system and method for fuel cell vehicles.

### Background

A fuel cell is a device that converts the chemical energy produced by fuel oxidation into electrical energy, functioning as a type of power generation system. Like a conventional chemical cell, a fuel cell relies on oxidation and reduction reactions. However, unlike a chemical cell, which operates in a closed system, a fuel cell continuously receives reactants from an external source and removes reaction products as they form.

In recent years, fuel cells have gained practical significance. Because their primary byproduct is pure water, they are being actively explored as a clean energy source for environmentally friendly vehicles. To maximize energy efficiency, fuel cell vehicles are typically designed as hybrid systems that combine a primary energy source—the fuel cell—with a secondary energy storage device, such as a battery or supercapacitor.

A bidirectional converter is essential in these systems to maintain a stable fuel utilization rate and balance power between the fuel cell and the load by charging or discharging the energy storage device as needed. In practice, fuel cell hybrid vehicles operate by continuously supplying power from the fuel cell, while an electric vehicle (EV) battery supplements power when demand exceeds the fuel cell's output. Because the voltage ranges of the fuel cell (main power source) and the EV battery (auxiliary source) differ significantly, a bidirectional DC/DC converter (BDC) is required to manage battery charging and discharging. For electric vehicles a high-voltage battery is used to store energy and drive a motor, whereas a fuel cell vehicle generates electricity through a chemical reaction between hydrogen and oxygen to power its motor.

For both systems, the presence of high-voltage components introduces a critical safety concern: insulation resistance degradation. If insulation resistance falls below safety standards, it poses a risk to occupants. Thus, there is a need for improved insulation resistance measurement systems and methods for fuel cell vehicles that monitor insulation resistance regularly and issue warnings or restrict vehicle operation when unsafe conditions are detected.

### SUMMARY

Disclosed herein is an insulation resistance measurement system and method for fuel cell vehicles, and more particularly to an insulation resistance measurement system and method for fuel cell vehicles enabling the reliability of a measured value of insulation resistance in consideration of the output (voltage fluctuation) characteristics of a vehicle to be secured.

It is an aspect of the present disclosure to provide an insulation resistance measurement system and method for fuel cell vehicles capable of determining an insulation resistance measurement period, a rest period, and a voltage stabilization confirmation point in a relay on state of an insulation resistance measurement circuit for measuring insulation resistance, and selectively adjusting a point at which the completion of voltage stabilization is confirmed such that the insulation resistance is measured in the state in which the voltage is stabilized, and therefore it is possible to secure reliability of insulation resistance measurement.

The aspects of the present disclosure are not limited to that described above. The aspects of the present disclosure will be clearly understood from the following description of embodiments and could be implemented by means defined in the claims and a combination thereof.

An insulation resistance measurement system for fuel cell vehicles according to an embodiment of the present disclosure includes an insulation resistance measurement circuit connected to an output terminal of a fuel cell configured to supply power, the insulation resistance measurement circuit being configured to measure an insulation resistance value of a fuel cell vehicle, a voltage measurement circuit configured to measure the voltage at the output terminal of the fuel cell in an on/off state of a relay provided in the insulation resistance measurement circuit, and a controller configured to control on/off of the relay based on the voltage measured at the output terminal, to determine whether the voltage measured in the on state of the relay is stabilized, and to determine insulation resistance using the voltage measured in a stabilized state of the voltage.

The controller may selectively control the relay of the output terminal at which a relatively high voltage is measured to be turned on and determine whether the voltage output from the output terminal with the relay on is stabilized.

The controller may determine an insulation resistance measurement period and a rest period, and determine a voltage stabilization confirmation point in the insulation resistance measurement period after the relay turns on.

The controller may determine a stabilization progress of the voltage by comparing a rise and fall average value of the voltage with a set threshold range between the voltage stabilization confirmation point and a set voltage stabilization completion confirmation point.

Based on the rise and fall average value being within the threshold range, the controller may determine that voltage stabilization is in progress and compare the difference between a first voltage measured at the voltage stabilization completion confirmation point and a second voltage measured immediately before the relay is turned off.

Based on the difference between the first voltage and the second voltage exceeding a set voltage, the controller may perform control such that the relay on state is extended.

Based on the difference between the first voltage and the second voltage being equal to or less than a set voltage, the controller may determine that the voltage stabilization is completed and determine the insulation resistance of the fuel cell vehicle.

Based on the rise and fall average value not being within the threshold range, the controller may determine that a fluctuation of the voltage has occurred, stop measuring the voltage, and perform control such that the rest period is extended.

The controller may perform control such that the insulation resistance of the fuel cell vehicle is updated and, based on determining that the insulation resistance to be updated is less than a set reference insulation resistance, perform control such that the insulation resistance measurement period and the rest period are shortened.

An insulation resistance measurement method for fuel cell vehicles according to another embodiment of the present disclosure includes a discharge resistance connection step of controlling, through a controller, a relay of an insulation resistance measurement circuit to be turned on based on the voltage measured at an output terminal of the fuel cell, a set point determination step of determining, through the controller, an insulation resistance measurement period and a rest period and determining a voltage stabilization confirmation point in the insulation resistance measurement period after the relay turns on, a stabilization determination step of determining, through the controller, a stabilization progress of the voltage by comparing the voltage measured between the voltage stabilization confirmation point and a voltage stabilization completion confirmation point set by extending from the voltage stabilization confirmation point, and an insulation resistance determination step of determining, through the controller, insulation resistance using the voltage measured in a stabilized state of the voltage.

The discharge resistance connection step may include controlling the relay of the output terminal at which a relatively high voltage is measured to be turned on and determining whether the voltage output from the output terminal with the relay on is stabilized.

The stabilization determination step may include determining a stabilization progress of the voltage by comparing a rise and fall average value of voltages measured at the voltage stabilization confirmation point and at the voltage stabilization confirmation completion point with a set threshold range.

The stabilization determination step may include determining that voltage stabilization is in progress based on the rise and fall average value being within the threshold range.

The stabilization determination step may include comparing the difference between a first voltage measured at the voltage stabilization completion confirmation point and a second voltage measured immediately before the relay is turned off based on determining that voltage stabilization is in progress.

The stabilization determination step may include performing control such that the relay on state is extended based on the difference between the first voltage and the second voltage exceeding a set voltage.

The stabilization determination step may include determining that the voltage stabilization is completed and performing control, through the controller, such that the insulation resistance determination step is performed based on the difference between the first voltage and the second voltage being equal to or less than the set voltage.

The stabilization determination step may include determining that a fluctuation of the voltage has occurred, stopping measuring the voltage, and performing control such that the rest period is extended based on the rise and fall average value not being within the threshold range.

The insulation resistance determination step may include performing control, through the controller, such that the determined insulation resistance is updated and performing control such that the insulation resistance measurement period and the rest period are shortened based on determining that the insulation resistance to be updated is less than a set reference insulation resistance.

Other aspects and preferred embodiments of the present disclosure are discussed infra.

### BRIEF DESCRIPTION OF THE DRAWINGS

The above and other features of the present disclosure will now be described in detail with reference to certain exemplary embodiments thereof illustrated in the accompanying drawings which are given hereinbelow by way of illustration only, and thus are not limitative of the present disclosure, and wherein:

FIG. 1 is a view showing the configuration of an insulation resistance measurement system for fuel cell vehicles according to an embodiment of the present disclosure;

FIG. 2 is a view showing an insulation resistance measurement circuit and a voltage measurement circuit of the insulation resistance measurement system for fuel cell vehicles according to the embodiment of the present disclosure;

FIG. 3 is a view showing an insulation resistance measurement period of the insulation resistance measurement system for fuel cell vehicles according to the embodiment of the present disclosure;

FIG. 4 is a view showing a first embodiment of variation of the insulation resistance measurement period of the insulation resistance measurement system for fuel cell vehicles according to the embodiment of the present disclosure;

FIG. 5 is a view showing a second embodiment of variation of the insulation resistance measurement period of the insulation resistance measurement system for fuel cell vehicles according to the embodiment of the present disclosure;

FIG. 6 is a view showing a third embodiment of variation of the insulation resistance measurement period of the insulation resistance measurement system for fuel cell vehicles according to the embodiment of the present disclosure; and

FIG. 7 is a view sequentially showing an insulation resistance measurement method for fuel cell vehicles according to another embodiment of the present disclosure.

It should be understood that the appended drawings are not necessarily to scale, presenting a somewhat simplified representation of various preferred features illustrative of the basic principles of the present disclosure. The specific design features of the present disclosure as disclosed herein, including, for example, specific dimensions, orientations, positions, and shapes, will be determined in part by the particular intended application and use environment.

In the FIGURES, reference numbers refer to the same or equivalent parts of the present disclosure throughout the several FIGURES of the drawing.

### DETAILED DESCRIPTION

Hereinafter, preferred embodiments according to the present disclosure will be described in detail with reference to the accompanying drawings.

Advantages and features of the present disclosure and methods for achieving the same will be clearly understood with reference to the following detailed description of embodiments in conjunction with the accompanying drawings.

However, the present disclosure is not limited to the embodiments disclosed herein and may be implemented in various different forms. The embodiments are merely given to make the disclosure of the present disclosure perfect and to perfectly instruct the scope of the disclosure to those skilled in the art, and the present disclosure should be defined by the scope of claims.

Furthermore, in describing the present disclosure, a detailed description of the related prior art will be omitted when the same may obscure the subject matter of the present disclosure.

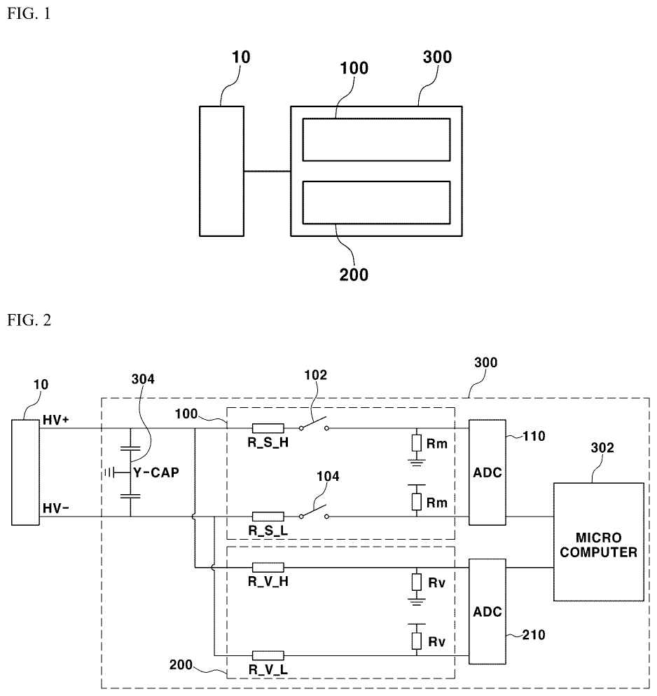

FIG. 1 is a view showing the configuration of an insulation resistance measurement system for fuel cell vehicles according to an embodiment of the present disclosure, and FIG. 2 is a view showing an insulation resistance measurement circuit and a voltage measurement circuit of the insulation resistance measurement system for fuel cell vehicles according to the embodiment of the present disclosure.

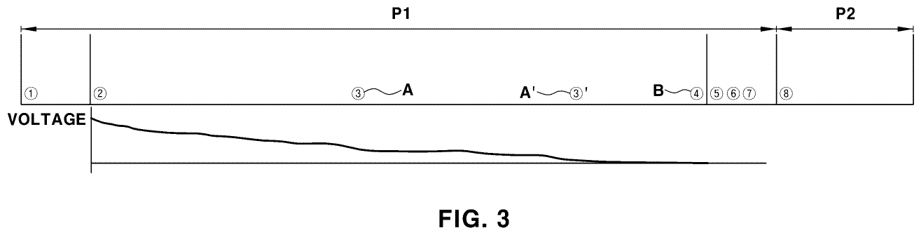

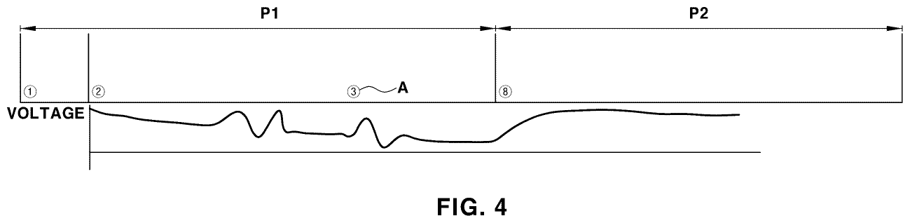

FIG. 3 is a view showing an insulation resistance measurement period of the insulation resistance measurement system for fuel cell vehicles according to the embodiment of the present disclosure, and FIG. 4 is a view showing a first embodiment of variation of the insulation resistance measurement period of the insulation resistance measurement system for fuel cell vehicles according to the embodiment of the present disclosure.

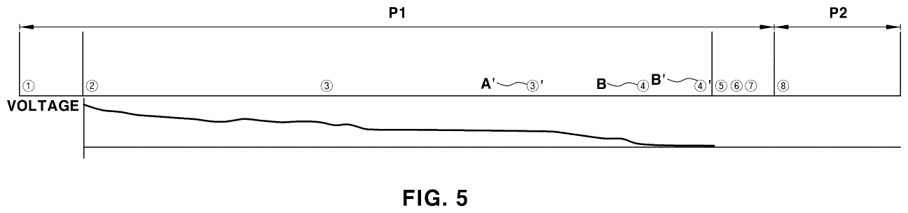

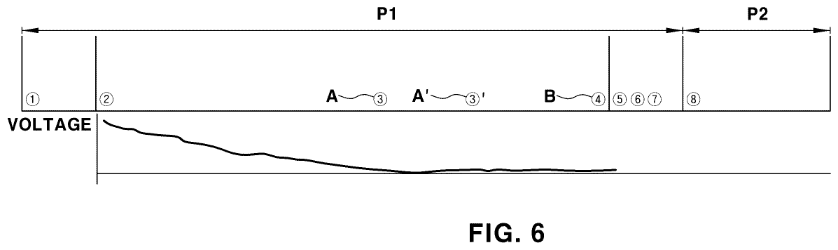

In addition, FIG. 5 is a view showing a second embodiment of variation of the insulation resistance measurement period of the insulation resistance measurement system for fuel cell vehicles according to the embodiment of the present disclosure, and FIG. 6 is a view showing a third embodiment of variation of the insulation resistance measurement period of the insulation resistance measurement system for fuel cell vehicles according to the embodiment of the present disclosure.

Typically, fuel cell vehicles are required by high-voltage safety legislation to be monitored for insulation resistance at all times, and to be equipped with a driver warning system to communicate this information to a driver in the event of insulation resistance degradation.

That is, it is required to measure and monitor the resistance at all times to quantitatively compare the degree of electrical leakage between a high-voltage battery and electrical parts connected to the high-voltage battery and the ground of the vehicle's chassis, and to warn the driver of the problem of reduced insulation resistance, such as prohibiting driving of the vehicle or limiting the driving performance, if the insulation resistance does not meet safety standards.

In measuring the insulation resistance as described above, conventionally, voltages V₁ and V₂ of output terminals HV+ and HV− of a fuel cell are measured to selectively switch to a relay on state, and voltages V_{1′} and V_{2′} of the output terminals are measured to determine the insulation resistance in a relay off state, for example, using the following [Equation 1] and [Equation 2] (see FIG. 2).

$$Ri = {R}_{0} \times {V}_{b} \times ( \frac{1}{{V}_{1 ’}} - \frac{1}{{V}_{1}} ) \qquad [ Equation 1 ]$$

$$Ri = Ro ( 1 + V 2 / V 1 ) ( ( V 1 - V 1 ’ ) / V 1 ’ )$$

(If V₁≥V₂, the insulation resistance is determined with the relay on the HV-side of the output terminal turned on)
R₀: Insertion resistance value for insulation resistance measurement (Rs+Rm)
V_{b}: Stack voltage (stack voltage just before the relay is turned on)
V_{b′}: Stack voltage (stack voltage at relay on)
V₁: HV− to GND voltage (voltage just before relay on)
V₁: HV− to GND voltage from relay on state to just before relay off after stabilization

$$Ri = {R}_{0} \times {V}_{b} \times ( \frac{1}{{V}_{2 ’}} - \frac{1}{{V}_{2}} ) \qquad [ Equation 2 ]$$

$$Ri = Ro ( 1 + V 1 / V 2 ) ( ( V 2 - V 2 ’ ) / V 2 ’ )$$

(If V₁<V₂, the insulation resistance is determined with the relay on the HV+ side of the output terminal turned on)
R₀: Insertion resistance value for insulation resistance measurement (Rs+Rm)
V_{b}: Stack voltage (stack voltage just before the relay is turned on)
V_{b′}: Stack voltage (stack voltage at relay on)
V₂: HV+ to GND voltage (voltage just before relay on)
V₂: HV+ to GND voltage from relay on state to just before relay off after stabilization

However, conventionally, when determining the insulation resistance, the voltage is measured after a predetermined period of time in a discharge resistance insertion state, i.e., in a relay on state, and the insulation resistance is determined using the voltage measured through [Equation 1] and [Equation 2] in a relay off state, but since the voltage variability of the fuel cell and the battery is very large, the voltage may not be stabilized when determining the insulation resistance, and noise may be generated due to the insulation resistance measurement.

For this reason, it is necessary to enable determination of the insulation resistance to be performed in a state of determining whether the voltage is stabilized.

As shown in FIG. 1 and FIG. 2, the insulation resistance measurement system includes an insulation resistance measurement circuit 100, a voltage measurement circuit 200, and a controller 300.

The insulation resistance measurement circuit 100 is connected to output terminals HV+ and HV− of the fuel cell configured to supply power, and measures the insulation resistance value of a fuel cell vehicle (see FIG. 2).

In addition, the voltage measurement circuit 200 measures voltages V₁ and V₂ of the output terminals HV+ and HV− of the fuel cell 10 in an on/off state for relays 102 and 104 provided in the insulation resistance measurement circuit 100.

The controller 300 may include a microcomputer 302 connected to analog-to-digital converters (ADC) 110 and 210 connected to the insulation resistance measurement circuit 100 and voltage measurement circuit 200, and controls on/off of the relays 102 and 104 based on the voltages V₁ and V₂ measured at the output terminals HV+ and HV−.

The controller 300 may be a conventional fuel cell stack voltage monitor (FSVM) including the insulation resistance measurement circuit 100 and the voltage measurement circuit 200, and may measure the insulation resistance based on the voltage of the fuel cell 10 using a resistance partial pressure measurement method through the insulation resistance measurement circuit 100 and the voltage measurement circuit 200.

Along with this, the controller 300 determines whether the voltage measured in the on state of the relays 102 and 104 is stabilized or not, and determines the insulation resistance of the fuel cell vehicle in the off state of the relays 102 and 104 based on the insulation resistance value and voltage measured by the insulation resistance measurement circuit 100 and the voltage measurement circuit 200 according to [Equation 1] and [Equation 2].

The controller 300 measures and compares the voltages V₁ and V₂ of the output terminals HV+ and HV−, and if the voltage V₂ output from the output terminal from which a relatively high voltage is measured, such as HV+, is greater than the voltage V₁ output from HV−, the controller 300 controls the relay 102 on, and determines whether the voltage output from the output terminal HV+ with the relay 102 on is stabilized.

Conversely, if the voltage V₂ output from HV+ is less than the voltage V₁ output from HV−, the controller 300 may turn on the relay 104 and determine whether the voltage output from the output terminal HV− with the relay 104 on is stabilized.

In order to determine whether the voltage is stabilized before the insulation resistance determination, the controller 300 determines an insulation resistance measurement period P1 and a rest period P2, as shown in FIG. 3, and determines a voltage stabilization confirmation point A in the insulation resistance measurement period P1 after the relay turns on.

This is because the fuel cell and the battery have very large voltage variability, and if the voltage is not stabilized when determining the insulation resistance, noise may be generated according to the insulation resistance measurement. In order to ensure the reliability of the insulation resistance determination, therefore, it is first determined whether the voltage is stabilized before determining the insulation resistance.

The controller 300 compares the rise and fall average value of the voltage with a set threshold range between the voltage stabilization confirmation point A and a voltage stabilization completion confirmation point A′, which is set as the point in time after a predetermined time has elapsed from the voltage stabilization confirmation point A, and determines the stabilization progress of the voltage.

Here, the controller 300 determines that voltage stabilization is in progress if the rise and fall average value is within the threshold range.

For example, if the rise and fall average value C of the voltage moving between the voltage stabilization confirmation point A and the voltage stabilization completion confirmation point A′ satisfies “−3_{(cal)}<C≤0”, it may be determined that the voltage is being stabilized in a discharge direction.

For example, in a dynamic driving mode, when the driver's required output increases, the voltage drops in a downward direction and then returns to the no-load voltage again, causing voltage fluctuations that may act as noise in the insulation resistance measurement, and since the driver's required output changes even when the relay is on, the voltage may rise and fall repeatedly, making it difficult to secure the reliability of the insulation resistance measurement.

However, as described above, when the rise and fall average value C of the voltage is within the set threshold range, it may be determined that the voltage is being stabilized, and therefore, in the state in which the voltage is stabilized, the voltage is measured and the relay is switched off. At this time, the measured voltages V₁ and V₂ are used to determine the insulation resistance for updating at a voltage measurement point B set in the insulation resistance measurement period.

Meanwhile, as another embodiment, if, as shown in FIG. 4, it is determined that the rise and fall average value C does not exist within the aforementioned critical range, for example, “−3_{(cal)}<C≤0” is not satisfied, in the time from the voltage stabilization confirmation point A to the voltage stabilization completion confirmation point A′, it is determined that a voltage fluctuation such as a voltage bounce occurs, and the voltage measurement is stopped midway, and the rest period P1 is controlled to be extended to secure time for the voltage to be stabilized.

In addition, as shown in FIG. 5, if, by comparing a difference between a first voltage measured at the voltage stabilization completion confirmation point A′ where voltage stabilization is in progress and a second voltage measured at the voltage measurement point B just before the relay is turned off, it is determined that the difference between the first voltage and the second voltage exceeds a set voltage, such as ±1_{(cal)}, the controller selectively performs control such that the state in which the relay is on is extended.

For example, if the vehicle is a vehicle in which a Y-CAPACITOR 304 included in the fuel cell stack voltage monitor (FSVM) corresponding to the controller 300 is large, or if the insulation resistance value is maintained due to the initial design of the high-voltage component, the difference between the first voltage and the second voltage may exceed the set voltage, and in this state, the controller 300 may determine that there is insufficient time for the voltage to be stabilized in the discharge direction. Consequently, the controller 300 performs control such that the point in time at which the relay is turned off is extended, and determines whether the voltage stabilization is finally achieved through the voltage difference between the voltage measurement point B and a voltage measurement confirmation point B′ set as the point in time after a predetermined time elapses from the voltage measurement point B.

Meanwhile, as another embodiment, the controller 300 performs control to update the insulation resistance of the fuel cell vehicle with the determined insulation resistance, as shown in FIG. 6, but performs control to shorten the insulation resistance measurement period P1 and the rest period P2 when it is determined that the insulation resistance to be so updated is less than a set reference insulation resistance.

In general, depending on the insulation resistance state, a difference in the discharge rate occurs in the relay on state, and if the insulation resistance is low, the discharge rate may be relatively fast, and therefore the voltage stabilization completion confirmation point A′ may be advanced to shorten the insulation resistance measurement period P1, and the controller 300 may repeatedly perform the insulation resistance measurement as the insulation resistance measurement period P1 is shortened, which may increase the number of measurements of the insulation resistance within the same time.

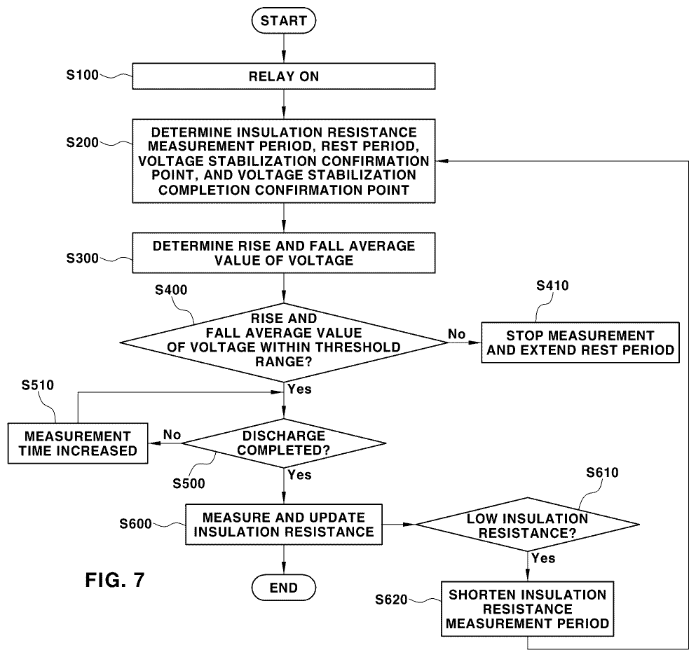

FIG. 7 is a view sequentially showing an insulation resistance measurement method for fuel cell vehicles according to another embodiment of the present disclosure.

The insulation resistance measurement method for fuel cell vehicles according to the present embodiment will be described sequentially with reference to FIG. 7.

First, the relays 102 and 104 of the insulation resistance measurement circuit 100 are selectively turned on through the controller 300 based on the voltages measured at the output terminals HV+ and HV− of the fuel cell (S100).

That is, the voltages V₁ and V₂ at the output terminals HV+ and HV− are measured and compared through the controller 300, if the voltage V₂ output from the output terminal at which a relatively high voltage is measured, e.g., HV+, is equal to greater than the voltage V₁ output from HV−, the relay 102 is turned on, and it is determined whether the voltage output from the output terminal HV+ with the relay 102 on is stabilized (see FIG. 2).

On the other hand, if the voltage V₂ output from the output terminal HV+ is less than the voltage V₁ output from HV−, the controller 300 turns on the relay 104 and determines whether the voltage output from the output terminal HV− with the relay 104 on is stabilized (see FIG. 2).

Subsequently, to determine whether the voltage is stabilized, the controller 300 determines an insulation resistance measurement period P1 and a rest period P2, and determines a voltage stabilization confirmation point A in the determined insulation resistance measurement period P1 after the relay turns on and a voltage stabilization completion confirmation point A′ set as the point in time after a predetermined time has elapsed from the voltage stabilization confirmation point A (S200).

At this time, the controller 300 determines the rise and fall average value of the voltage moving between the voltage stabilization confirmation point A and the set voltage stabilization completion confirmation point A′ (S300), and compares the rise and fall average value C of the voltage with a threshold range to determine the stabilization progress of the voltage.

That is, the controller 300 may determine (S400) that the voltage is in the process of being stabilized in the discharge direction based on determining that the rise and fall average value C of the voltage moving between the voltage stabilization confirmation point A and the voltage stabilization completion confirmation point A′ satisfies a threshold range, e.g., “−3_{(cal)}<C≤0”.

For example, in a dynamic driving mode, when the driver's required output increases, the voltage drops in the downward direction and then returns to the no-load voltage, causing voltage fluctuations that may act as noise in the insulation resistance measurement, and since the driver's required output changes even when the relay is on, the voltage may rise and fall repeatedly, making it difficult to secure reliability in the insulation resistance measurement.

However, as described above, when the rise and fall average value of the voltage is within a predetermined range, it may be determined that the voltage is being stabilized (S500), and therefore, in the state in which the voltage is stabilized, the voltage is measured, the relay is switched off, and the measured voltages V₁ and V₂ are used to determine the insulation resistance for updating in the voltage measurement period B (S600).

Meanwhile, based on determining that the rise and fall average value C is not within the threshold range, e.g., “−3_{(cal)}<C≤0”, in the time from the voltage stabilization confirmation point A to the voltage stabilization completion confirmation point A′ (S400), the controller 300 determines that the voltage fluctuation such as voltage bouncing occurs, stops the voltage measurement in order to secure time for the voltage to be stabilized, and performs control such that the rest period P2 to secure time for the voltage to be stabilized is extended (S410) (see FIG. 4).

In addition, based on determining that the voltage is being stabilized (S500), and the voltage is being stabilized in the discharge direction, but the discharge is not completed, the controller 300 performs control such that the relay on state is extended, i.e., the voltage measurement time is increased (S510).

That is, even if the rise and fall average value is within the threshold range (S400), the controller 300 compares the difference between the first voltage measured at the voltage stabilization completion confirmation point A′ and the second voltage measured at the voltage measurement period B just before the relay is turned off, and if the difference between the first voltage and the second voltage exceeds a set voltage, the controller 300 performs control such that the relay on state is extended (S510) (see FIG. 5).

For example, if the vehicle is a vehicle in which the Y-CAPACITOR 304 included in the fuel cell stack voltage monitor (FSVM) corresponding to the controller 300 is large, or if the insulation resistance value is maintained due to the initial design of the high-voltage component, the difference between the first voltage and the second voltage may exceed the set voltage, and in this state, the controller 300 may determine that there is insufficient time for the voltage to be stabilized in the discharge direction. Consequently, the controller 300 performs control such that the point in time at which the relay is turned off is extended, and determines whether the voltage stabilization is finally achieved through the voltage difference between the voltage measurement point B and a voltage measurement confirmation point B′ set as the point in time after a predetermined time elapses from the voltage measurement point B.

Meanwhile, in controlling to update the insulation resistance of the fuel cell vehicle with the insulation resistance determined through the controller 300 (S600), based on determining that the insulation resistance to be updated is less than the set reference insulation resistance (S610), the insulation resistance measurement period P1 and the rest period P2 are controlled to be shortened (S620) (see FIG. 1).

In general, depending on the insulation resistance state, a difference in the discharge rate occurs in the relay on state, and if the insulation resistance is low, the discharge rate may be relatively fast, and therefore the voltage stabilization completion confirmation point A′ may be advanced such that the insulation resistance measurement period P1 is shortened, and the controller 300 may perform the insulation resistance measurement repeatedly as the insulation resistance measurement period P1 is shortened, and therefore it is possible to increase the number of measurements of the insulation resistance within the same time.

As is apparent from the foregoing, the present disclosure has the effect of determining the insulation resistance measurement period, the rest period, and the voltage stabilization confirmation point in the relay on state of the insulation resistance measurement circuit for measuring insulation resistance, and selectively adjusting the point at which the completion of voltage stabilization is confirmed such that the insulation resistance is measured in the state in which the voltage is stabilized, and therefore it is possible to secure the reliability of insulation resistance measurement.

In addition, the present disclosure has the effect of enabling accurate measurement of insulation resistance according to different high-voltage component capacities of the vehicle by extending the state in which the relay is on, i.e., increasing the time for voltage stabilization, based on determining that voltage stabilization has not been achieved according to the voltage measurement result at the point at which the completion of voltage stabilization is confirmed.

Furthermore, the present disclosure has the effect of performing control such that the voltage measurement interruption and the rest period are secured when a voltage fluctuation caused by an increase in the required power output of the driver occurs, and therefore it is possible to avoid the period where an error in the insulation resistance determination value occurs.

Although the present disclosure has been described with reference to the embodiment(s) shown in the drawings, which are merely illustrative, those skilled in the art will understand that various modifications are possible therefrom and all or some of the embodiment(s) may be selectively combined. Therefore, the real technical protection scope of the present disclosure is defined by the technical idea of the appended claims.

What is claimed is:

1. An insulation resistance measurement system for fuel cell vehicles, the insulation resistance measurement system comprising:
an insulation resistance measurement circuit connected to an output terminal of a fuel cell configured to supply power, the insulation resistance measurement circuit being configured to measure an insulation resistance value of a fuel cell vehicle;
a voltage measurement circuit configured to measure a voltage at the output terminal of the fuel cell in an on/off state of a relay provided in the insulation resistance measurement circuit; and
a controller configured to control on/off of the relay based on the voltage measured at the output terminal, to determine whether the voltage measured in the on state of the relay is stabilized, and to determine an insulation resistance using a voltage measured in a stabilized state of the voltage.

2. The insulation resistance measurement system according to claim 1, wherein the controller selectively controls the relay of the output terminal at which a relatively high voltage is measured to be turned on and determines whether a voltage output from the output terminal with the relay on is stabilized.

3. The insulation resistance measurement system according to claim 1, wherein the controller determines an insulation resistance measurement period and a rest period, and determines a voltage stabilization confirmation point in the insulation resistance measurement period after the relay turns on.

4. The insulation resistance measurement system according to claim 3, wherein the controller determines a stabilization progress of the voltage by comparing a rise and fall average value of the voltage with a set threshold range between the voltage stabilization confirmation point and a set voltage stabilization completion confirmation point.

5. The insulation resistance measurement system according to claim 4, wherein, based on the rise and fall average value being within the threshold range, the controller determines that voltage stabilization is in progress and compares a difference between a first voltage measured at the voltage stabilization completion confirmation point and a second voltage measured immediately before the relay is turned off.

6. The insulation resistance measurement system according to claim 5, wherein, based on the difference between the first voltage and the second voltage exceeding a set voltage, the controller performs control such that the relay on state is extended.

7. The insulation resistance measurement system according to claim 5, wherein, based on the difference between the first voltage and the second voltage being equal to or less than a set voltage, the controller determines that the voltage stabilization is completed and determines the insulation resistance of the fuel cell vehicle.

8. The insulation resistance measurement system according to claim 4, wherein, based on the rise and fall average value not being within the threshold range, the controller determines that a fluctuation of the voltage has occurred, stops measuring the voltage, and performs control such that the rest period is extended.

9. The insulation resistance measurement system according to claim 3, wherein the controller performs control such that the insulation resistance of the fuel cell vehicle is updated and, based on determining that the insulation resistance to be updated is less than a set reference insulation resistance, performs control such that the insulation resistance measurement period and the rest period are shortened.

10. An insulation resistance measurement method for fuel cell vehicles, the insulation resistance measurement method comprising:
a discharge resistance connection step of controlling, through a controller, a relay of an insulation resistance measurement circuit to be turned on based on a voltage measured at an output terminal of the fuel cell;
a set point determination step of determining, through the controller, an insulation resistance measurement period and a rest period and determining a voltage stabilization confirmation point in the insulation resistance measurement period after the relay turns on;
a stabilization determination step of determining, through the controller, a stabilization progress of the voltage by comparing a voltage measured between the voltage stabilization confirmation point and a voltage stabilization completion confirmation point set by extending from the voltage stabilization confirmation point; and
an insulation resistance determination step of determining, through the controller, an insulation resistance using a voltage measured in a stabilized state of the voltage.

11. The insulation resistance measurement method according to claim 10, wherein the discharge resistance connection step comprises controlling the relay of the output terminal at which a relatively high voltage is measured to be turned on and determining whether a voltage output from the output terminal with the relay on is stabilized.

12. The insulation resistance measurement method according to claim 10, wherein the stabilization determination step comprises determining a stabilization progress of the voltage by comparing a rise and fall average value of voltages measured at the voltage stabilization confirmation point and at the voltage stabilization confirmation completion point with a set threshold range.

13. The insulation resistance measurement method according to claim 12, wherein the stabilization determination step comprises determining that voltage stabilization is in progress based on the rise and fall average value being within the threshold range.

14. The insulation resistance measurement method according to claim 13, wherein the stabilization determination step comprises comparing a difference between a first voltage measured at the voltage stabilization completion confirmation point and a second voltage measured immediately before the relay is turned off based on determining that voltage stabilization is in progress.

15. The insulation resistance measurement method according to claim 14, wherein the stabilization determination step comprises performing control such that the relay on state is extended based on the difference between the first voltage and the second voltage exceeding a set voltage.

16. The insulation resistance measurement method according to claim 14, wherein the stabilization determination step comprises determining that the voltage stabilization is completed and performing control, through the controller, such that the insulation resistance determination step is performed based on the difference between the first voltage and the second voltage being equal to or less than a set voltage.

17. The insulation resistance measurement method according to claim 12, wherein the stabilization determination step comprises determining that a fluctuation of the voltage has occurred, stopping measuring the voltage, and performing control such that the rest period is extended based on the rise and fall average value not being within the threshold range.

18. The insulation resistance measurement method according to claim 10, wherein the insulation resistance determination step comprises performing control, through the controller, such that the determined insulation resistance is updated and performing control such that the insulation resistance measurement period and the rest period are shortened based on determining that the insulation resistance to be updated is less than a set reference insulation resistance.
